(19) United States
(12) Patent Application Publication
(10) Pub. No.: US 2025/0367782 A1
(43) Pub. Date: Dec. 4, 2025

(54) POLISHING APPARATUS AND POLISHING METHOD

(71) Applicant: EBARA CORPORATION, Tokyo (JP)

(72) Inventors: Masayoshi ITO, Tokyo (JP); Itsuki KOBATA, Tokyo (JP)

(21) Appl. No.: 19/298,735

(22) Filed: Aug. 13, 2025

Related U.S. Application Data
(63) Continuation of application No. 17/808,688, filed on Jun. 24, 2022.

(30) Foreign Application Priority Data
Jul. 7, 2021 (JP) 2021-112823

(51) Int. Cl. B24B 37/013; B24B 37/04; B24B 49/12

(52) U.S. Cl. CPC B24B 37/013; B24B 37/042; B24B 49/12

(57) ABSTRACT

A polishing apparatus capable of monitoring a distribution of an amount of liquid, such as a polishing liquid or a chemical liquid, on a polishing surface of a polishing pad, and capable of polishing an object, such as a wafer, under appropriate polishing conditions. The polishing apparatus includes: a polishing table configured to support a polishing pad; a polishing head configured to press the object against a polishing surface of the polishing pad; a liquid supply device configured to supply liquid onto the polishing surface; a liquid monitoring device configured to obtain optical information contained in light from a plurality of points on the polishing surface; an optical information analyzer configured to determine a distribution of amount of the liquid on the polishing surface from the optical information; and an operation controller configured to control operations of the polishing apparatus.

### CROSS REFERENCE TO RELATED APPLICATION

This document is a Continuation of U.S. patent application Ser. No. 17/808,688, filed Jun. 24, 2022, which claims priority to Japanese Patent Application No. 2021-112823 filed Jul. 7, 2021, the entire contents of which are hereby incorporated by reference.

### BACKGROUND

In manufacturing of semiconductor devices, various kinds of films are formed on a wafer. In forming processes of interconnects and contacts, the wafer is polished in order to remove unnecessary portions of the film and surface irregularities after a film forming process. Chemical mechanical polishing (CMP) is a typical technique for wafer polishing. This CMP is performed by pressing and rubbing the wafer against a polishing surface of a polishing pad while supplying a polishing liquid onto the polishing surface. The film formed on the wafer is polished by a combination of a chemical action of a chemical component of the polishing liquid and a mechanical action of the polishing pad and/or abrasive grains contained in the polishing liquid supplied onto the polishing surface.

A polishing apparatus configured to perform the CMP process includes a polishing table that supports the polishing pad and a polishing head for pressing the wafer, which is an object to be polished, against the polishing pad. This polishing apparatus is configured to press the wafer against the polishing surface of the polishing pad while supplying the polishing liquid from a liquid supply device onto the polishing surface of the polishing pad. The polishing table and the polishing head are rotated, so that the wafer is placed in sliding contact with the polishing surface. As a result, the surface of the wafer is polished to have a flat and mirror surface.

An accuracy required for each process in the recent manufacturing of semiconductor devices has already reached the order of several nm, and CMP is no exception. In addition, with the increase in integration of semiconductor integrated circuits, miniaturization and multi-layering are accelerating. Therefore, in order to realize these miniaturization and multi-layering, CMP is required to reduce a variation in residual film thickness after CMP within the order of several nm over the entire surface of the wafer.

In order to reduce the variation in the residual film thickness, it is necessary to control various factors that affect a polishing rate, such as a surface temperature of the polishing pad during polishing, an amount of polishing liquid supplied, and a distribution of the polishing liquid on the polishing pad. In the CMP process, after the polishing, a cleaning liquid, such as a chemical liquid or pure water (DIW), may be supplied onto the polishing pad through a liquid supply device, instead of the polishing liquid, for the purpose of cleaning the wafer surface. A distribution of an amount of cleaning liquid supplied also affects an uniformity of a cleaning performance on the wafer surface.

Further, in each process of manufacturing of semiconductor devices, it is required to reduce a cost of each process. In the CMP process, the polishing liquid is particularly targeted for cost reduction. The polishing liquid used in the CMP is expensive, and the disposal of the used polishing liquid is also costly. Therefore, in order to reduce the operating cost of the CMP apparatus and the manufacturing cost of the semiconductor devices, it is required to reduce the amount of the polishing liquid used.

The liquid supply device usually supplies the polishing liquid from a nozzle having a single supply port. In some polishing processes, an operation such as swinging the nozzle in parallel with the polishing pad is performed. Japanese laid-open patent publication No. 2006-147773 describes a device that efficiently supplies a polishing liquid onto a polishing surface of a polishing pad. Japanese laid-open patent publication No. 2006-147773 discloses a nozzle having a plurality of polishing-liquid supply ports and a nozzle having a slit-shaped supply port, and describes that efficient polishing can be performed by spreading the polishing liquid on the polishing pad.

As described above, the amount of polishing liquid supplied during polishing and the distribution of the amount of polishing liquid on the polishing pad greatly affect the polishing performance (variation in polishing rate) and polishing efficiency. Therefore, it is necessary to monitor the distribution of the amount of polishing liquid on the polishing pad in order to maintain the polishing performance and the polishing efficiency.

Causes that change the distribution of the amount of polishing liquid on the polishing pad include device failure, a change in physical properties (viscosity, etc.) of the polishing liquid due to a temperature rise of the polishing pad, and a change in a surface condition of the polishing pad. When the cause is a device failure, in most cases, such device failure is detected as an abnormal flow rate of the polishing liquid by a flow-rate sensor or the like. For example, when the liquid supply device has a nozzle with a single supply port, each nozzle is provided with a flow-rate sensor. When the liquid supply device is a nozzle having a plurality of supply ports, a flow-rate sensor is provided in a main flow passage communicating with the nozzle.

However, in the above-mentioned liquid supply device having the plurality of supply ports, when one of the plurality of supply ports is clogged, the change in the flow rate is distributed by the number of supply ports, so that the change in the flow rate of the main flow passage is small. Consequently, a flow-rate abnormal may not be determined, and as a result, clogging of the supply port may not be detected. To deal with this, there is an idea to arrange multiple flow-rate sensors in the multiple supply ports, respectively. However, it is necessary to increase the number of flow-rate sensors as the number of supply ports increases, and therefore, sensor installation spaces increase and sensor costs also increase.

Further, the polishing pad is worn by the polishing process, and the distribution of the amount of polishing liquid on the polishing pad surface changes due to a variation in the wear within the polishing pad surface. For example, when a size of a groove formed in the surface of the polishing pad (particularly a depth of the groove) is reduced due to the wear, the distribution of the amount of polishing liquid on the surface of the polishing pad changes even when the flow rate of the polishing liquid supplied is normal. This will result in a change and a variation in the polishing-rate distribution. These problems can occur when the liquid supplied to the polishing surface is a chemical liquid or pure water.

### SUMMARY

Therefore, there are provided a polishing apparatus and a polishing method capable of monitoring a distribution of an amount of liquid, such as a polishing liquid or a chemical liquid, on a polishing surface of a polishing pad, and capable of polishing an object, such as a wafer, under appropriate polishing conditions based on the distribution of the amount of liquid obtained by the monitoring.

Embodiments, which will be described below, relate to a polishing apparatus and a polishing method for polishing an object, such as a wafer, a substrate, or a panel, by pressing the object against a polishing surface of a polishing pad, and particularly relates to a polishing apparatus and a polishing method that rubs the object against the polishing pad in the presence of a polishing liquid, such as a slurry, on the polishing surface of the polishing pad.

In an embodiment, there is provided a polishing apparatus for polishing an object, comprising: a polishing table configured to support a polishing pad; a polishing head configured to press the object against a polishing surface of the polishing pad; a liquid supply device configured to supply liquid onto the polishing surface; a polishing-table rotating device configured to rotate the polishing table; a polishing-head rotating device configured to rotate the polishing head; a liquid monitoring device configured to obtain optical information contained in light from a plurality of points on the polishing surface; an optical information analyzer configured to determine a distribution of amount of the liquid on the polishing surface from the optical information; and an operation controller configured to control operations of the polishing apparatus.

In an embodiment, the operation controller is configured to instruct the liquid monitoring device to obtain first optical information of a plurality of points on the polishing surface before supply of the liquid, and further instruct the liquid monitoring device to obtain second optical information of a plurality of points on the polishing surface when the liquid is supplied, and the optical information analyzer is configured to determine a first distribution from the first optical information, determine a second distribution from the second optical information, and determine a distribution of the amount of the liquid by subtracting the first distribution from the second distribution.

In an embodiment, the operation controller is configured to instruct the liquid monitoring device to obtain the optical information of a plurality of points on the polishing surface at a plurality of points in time during polishing of the object, and the optical information analyzer is configured to obtain a temporal transition of the distribution of the amount of the liquid on the polishing surface from the optical information of the plurality of points of the polishing surface obtained at the plurality of points in time.

In an embodiment, the operation controller is configured to instruct the liquid monitoring device to obtain the optical information at an interval time before or after polishing of the object.

In an embodiment, the operation controller is configured to instruct the liquid monitoring device to obtain initial optical information of a plurality of points on the polishing surface of the polishing pad that has not been used for polishing yet and current optical information of a plurality of points on the polishing surface of the polishing pad that has been used for polishing, the optical information analyzer is configured to determine an initial distribution of the amount of the liquid from the initial optical information, and determine a current distribution of the amount of the liquid on the polishing surface from the current optical information, and the operation controller is configured to calculate a difference between the initial distribution and the current distribution.

In an embodiment, the operation controller is configured to instruct the liquid supply device to supply the liquid onto the polishing surface of the polishing pad while the liquid monitoring device is obtaining the optical information, the liquid being of a different type from a polishing liquid used for polishing of the object.

In an embodiment, the polishing apparatus further comprises a light source configured to irradiating the polishing surface with light having one or more wavelengths in a range of 200 nm to 1100 nm.

In an embodiment, the liquid monitoring device has a light-detection sensor configured to measure quantity of light having one or more wavelengths in a range of 200 nm to 1100 nm.

In an embodiment, the optical information analyzer is configured to determine the distribution of the amount of the liquid on the polishing surface based on measurement data of the quantity of light.

In an embodiment, the liquid monitoring device has an image sensor configured to generate a color image.

In an embodiment, the optical information analyzer is configured to determine the distribution of the amount of the liquid on the polishing surface by analyzing the optical information which is a color distribution appearing on the color image.

In an embodiment, the liquid monitoring device is arranged so as to obtain the optical information of the plurality of points in a monitoring region located upstream of the polishing head in a rotation direction of the polishing table.

In an embodiment, the operation controller is configured to calculate a difference between a plurality of distributions of the amount of the liquid on the polishing surface determined at the plurality of points in time during polishing of the object, and change polishing conditions for the object in a direction as to reduce the difference in distribution when the difference in distribution is larger than a permissible value.

In an embodiment, the operation controller is configured to recalculate a difference between a plurality of distributions of the amount of the liquid determined during polishing of the object after the polishing conditions are changed, and stop operation of the polishing apparatus before polishing of a next object when the recalculated difference in distribution is larger than the permissible value.

In an embodiment, the operation controller is configured to calculate a difference between a plurality of distributions of the amount of the liquid determined at the plurality of points in time during polishing of the object, and stop operation of the polishing apparatus before polishing of a next object when the difference in distribution is larger than a permissible value.

In an embodiment, the operation controller is configured to calculate a difference between a plurality of distributions of the amount of the liquid determined at the plurality of points in time during polishing of the object, and change a pressing force of the polishing head against the object when the difference in distribution is larger than a permissible value.

In an embodiment, the operation controller is configured to change polishing conditions for the object in a direction as to reduce the difference between the initial distribution and the current distribution of the amount of the liquid on the polishing surface when the difference is larger than a threshold value.

In an embodiment, the operation controller is configured to recalculate a difference between the initial distribution of the amount of the liquid and a current distribution of the amount of the liquid that has been newly determined after the polishing conditions have been changed, and stop polishing operation of the polishing apparatus before polishing of a next object when the difference in distribution is larger than the threshold value.

In an embodiment, the operation controller is configured to stop polishing operation of the polishing apparatus before polishing of a next object when the difference between the initial distribution and the current distribution of the amount of the liquid on the polishing surface is larger than a threshold value.

In an embodiment, the operation controller is configured to determine that an abnormality has occurred in the polishing apparatus when the distribution of the amount of the liquid on the polishing surface falls below a preset threshold distribution of the amount of the liquid.

In an embodiment, the liquid is one of a polishing liquid, pure water, a chemical liquid, and colored water.

In an embodiment, there is provided a polishing method for polishing an object, comprising: while rotating a polishing head and a polishing table supporting a polishing pad, pressing the object against a polishing surface of the polishing pad by the polishing head to polish the object; before, during, or after polishing of the object, obtaining optical information contained in light from a plurality of points on the polishing surface, while supplying a liquid onto the polishing surface; and determining a distribution of amount of the liquid on the polishing surface from the optical information.

In an embodiment, the distribution of the amount of the liquid is determined by subtracting a first distribution from a second distribution, the first distribution being determined from first optical information of a plurality of points on the polishing surface obtained before the supply of the liquid, and the second distribution being determined from second optical information of a plurality of points on the polishing surface obtained when the liquid is supplied.

In an embodiment, obtaining the optical information comprises obtaining the optical information of a plurality of points on the polishing surface at a plurality of points in time during polishing of the object while supplying the liquid onto the polishing surface, and determining the distribution of the amount of the liquid comprises obtaining a temporal transition of the distribution of the amount of the liquid on the polishing surface from the optical information of the plurality of points on the polishing surface obtained at the plurality of points in time.

In an embodiment, obtaining the optical information comprises obtaining the optical information while supplying the liquid onto the polishing surface at an interval time before or after polishing of the object.

In an embodiment, the polishing method further comprises: obtaining initial optical information of a plurality of points on the polishing surface while supplying the liquid onto the polishing surface of the polishing pad that has not been used for polishing yet; obtaining current optical information of a plurality of points on the polishing surface while supplying the liquid onto the polishing surface of the polishing pad that has been used for polishing; determining an initial distribution of the amount of the liquid on the polishing surface from the initial optical information; determining a current distribution of the amount of the liquid on the polishing surface from the current optical information; and calculating a difference between the initial distribution and the current distribution.

In an embodiment, the liquid supplied onto the polishing surface of the polishing pad while obtaining the optical information is a liquid of a different type from a polishing liquid used for polishing of the object.

In an embodiment, the optical information is quantity of light from the polishing surface.

In an embodiment, the optical information is a color distribution of the polishing surface.

In an embodiment, obtaining the optical information comprises obtaining the optical information of the plurality of points in a monitoring region located upstream of the polishing head in a rotation direction of the polishing table.

In an embodiment, the polishing method further comprises: calculating a difference between a plurality of distributions of the amount of the liquid at the plurality of points in time during polishing of the object; and changing polishing conditions for the object in a direction as to reduce the difference in distribution when the difference in distribution is larger than a permissible value.

In an embodiment, the polishing method further comprises: recalculating a difference between a plurality of distributions of the amount of the liquid determined at a plurality of points in time during polishing of the object after the polishing conditions are changed; and stopping operation of a polishing apparatus before polishing of a next object when the recalculated difference in distribution is larger than the permissible value.

In an embodiment, the polishing method further comprises: calculating a difference between a plurality of distributions of the amount of the liquid determined at the plurality of points in time during polishing of the object; and stopping operation of a polishing apparatus before polishing of a next object when the difference in distribution is larger than a permissible value.

In an embodiment, the polishing method further comprises: calculating a difference between a plurality of distributions of the amount of the liquid determined at the plurality of points in time during polishing of the object; and changing a pressing force of the polishing head against the object when the difference in distribution is larger than a permissible value.

In an embodiment, the polishing method further comprises: changing polishing conditions for the object in a direction as to reduce the difference between the initial distribution and the current distribution of the amount of the liquid on the polishing surface when the difference is larger than a threshold value.

In an embodiment, the polishing method further comprises: recalculating a difference between the initial distribution of the amount of the liquid and a current distribution of the amount of the liquid that has been newly determined after the polishing conditions have been changed; and stopping operation of a polishing apparatus before polishing of a next object when the difference in distribution is larger than the threshold value.

In an embodiment, the polishing method further comprises: stopping operation of a polishing apparatus before polishing of a next object when the difference between the initial distribution and the current distribution of the amount of the liquid on the polishing surface is larger than a threshold value.

In an embodiment, the polishing method further comprises: determining that an abnormality has occurred in a polishing apparatus when the distribution of the amount of the liquid falls below a preset threshold distribution of the amount of the liquid.

In an embodiment, the liquid is one of a polishing liquid, pure water, a chemical liquid, and colored water.

According to the above-described embodiments, it is possible to monitor the distribution itself of the amount of liquid, such as a polishing liquid or a chemical liquid, on the polishing pad. Further, by feeding back the monitoring result to the operation of the polishing apparatus, the polishing apparatus can polish the object, such as a wafer, under appropriate polishing conditions.

### BRIEF DESCRIPTION OF THE DRAWINGS

FIG. 1 is a perspective view schematically showing an embodiment of a polishing apparatus;

FIG. 2 is a cross-sectional view of a polishing head shown in FIG. 1;

FIG. 3 is a plan view of a polishing pad, a liquid supply device, and the polishing head;

FIG. 4 is a diagram showing an example of a graph of a distribution of amount of a polishing liquid;

FIG. 5 is a diagram showing an example of a graph of the distribution of the amount of polishing liquid;

FIGS. 6A and 6B are graphs each showing the distribution of the amount of polishing liquid changed during polishing of one wafer;

FIG. 7 is a graph showing a manner in which the entire distribution of the amount of polishing liquid decreases due to an abnormality in the polishing apparatus;

FIG. 8 is a graph illustrating a change in a distribution of amount of liquid when one of a plurality of supply ports is clogged;

FIG. 9 is a graph showing an initial distribution and a current distribution of the amount of liquid;

FIG. 10 is a graph illustrating an embodiment for determining whether or not a difference between the distributions of the amount of the liquid is within a predetermined range;

FIG. 11 is a graph illustrating a change in the distribution of the amount of liquid when one of a plurality of supply ports is clogged;

FIG. 12A is a graph showing a first distribution obtained from first optical information obtained before supply of a liquid;

FIG. 12B is a graph showing a second distribution obtained from second optical information obtained when the liquid is supplied; and

FIG. 12C is a graph showing a distribution of the amount of liquid obtained by subtracting the first distribution from the second distribution.

### DESCRIPTION OF EMBODIMENTS

Hereinafter, embodiments will be described with reference to the drawings.

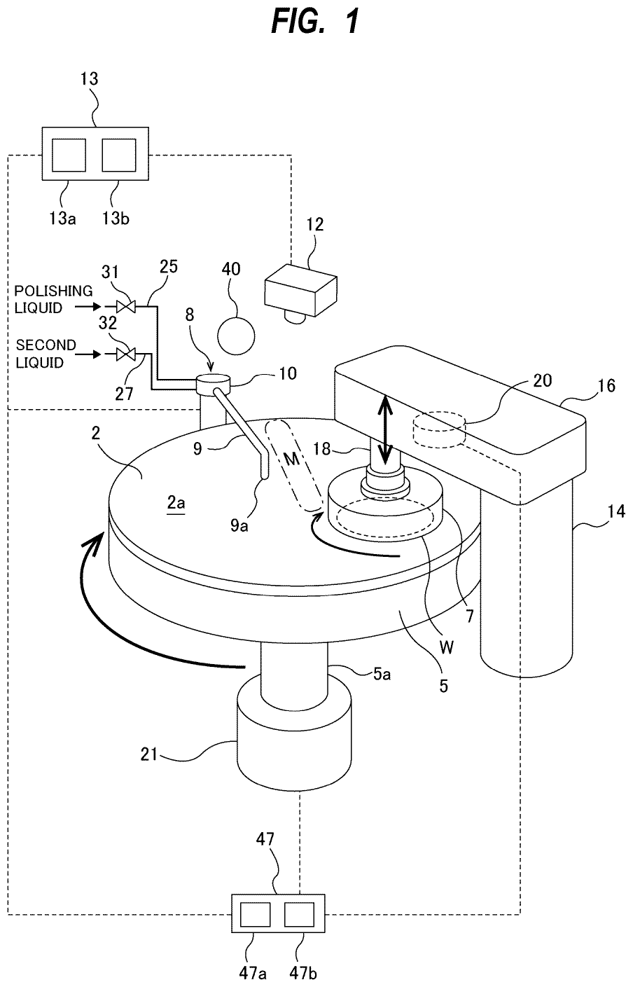

FIG. 1 is a perspective view schematically showing an embodiment of a polishing apparatus. As shown in FIG. 1, the polishing apparatus includes a polishing table 5 configured to a polishing pad 2 having a polishing surface 2a, a polishing head 7 configured to press a wafer W (which is an object to be polished) against the polishing surface 2a, a liquid supply device 8 configured to supply a liquid (e.g., a polishing liquid) to the polishing surface 2a, a liquid monitoring device 12 configured to obtain optical information contained in a light from the polishing surface 2a, an optical information analyzer 13 configured to determine a distribution of an amount of the liquid on the polishing surface 2a obtained by the liquid monitoring device 12, and an operation controller 47 configured to control operations of the polishing apparatus.

The polishing head 7 is configured to hold the wafer W on a lower surface thereof by vacuum suction or the like. In this embodiment, the wafer W is circular. The object to be polished is not limited to the wafer as long as it is a workpiece used for manufacturing of semiconductor devices. Other examples of the object to be polished include square wafer, substrate, panel, and the like.

The polishing apparatus further includes a support shaft 14, a polishing-head oscillation arm 16 coupled to an upper end of the support shaft 14 and configured to oscillate the polishing head 7, a polishing-head shaft 18 rotatably supported by a free end of the polishing-head oscillation arm 16, and a polishing-head rotating device 20 configured to rotate the polishing head 7 about its axis. The polishing-head rotating device 20 is fixed to the polishing-head oscillation arm 16 and is coupled to the polishing-head shaft 18 via a torque transmission mechanism (not shown) including a belt, pulleys, etc. The polishing head 7 is coupled to a lower end of the polishing-head shaft 18. The polishing-head rotating device 20 rotates the polishing-head shaft 18 via the torque transmission mechanism, and the polishing head 7 rotates together with the polishing-head shaft 18. In this way, the polishing head 7 is rotated by the polishing-head rotating device 20 in a direction indicated by arrow about the axis of the polishing head 7. A specific example of the polishing-head rotating device 20 is an electric motor.

The polishing-head shaft 18 can be moved up and down relative to the polishing-head oscillation arm 16 by an elevating mechanism (not shown), so that the polishing head 7 can be moved up and down by the vertical movement of the polishing-head shaft 18 with respect to the polishing-head oscillation arm 16.

The polishing apparatus further includes a polishing-table rotating device 21 configured to rotate the polishing pad 2 and the polishing table 5 about their axes. The polishing table 5 is coupled to the polishing-table rotating device 21 via a table shaft 5a. The polishing table 5 and the polishing pad 2 are rotated about the table shaft 5a by the polishing-table rotating device 21 in a direction indicated by arrow. The polishing pad 2 is attached to an upper surface of the polishing table 5. An upper surface of the polishing pad 2 constitutes the polishing surface 2a for polishing the wafer W. A specific example of the polishing-table rotating device 21 is an electric motor.

The liquid supply device 8 is coupled to a liquid nozzle 9 having a supply port 9a at its distal end, a nozzle oscillation mechanism 10 configured to oscillate the supply port 9a of the liquid nozzle 9 in a radial direction of the polishing pad 2, a first liquid supply line 25 and a second liquid supply line 27 coupled to the liquid nozzle 9, and a first flow-rate regulation valve 31 and a second flow-rate regulation valve 32 attached to the first liquid supply line 25 and the second liquid supply line 27, respectively. The first liquid supply line 25 is a line for supplying the polishing liquid (typically slurry) as a first liquid to the liquid nozzle 9, and the second liquid supply line 27 is a line for supplying to the liquid nozzle 9 a liquid (for example, pure water, chemical liquid, or colored water) which is a different type from the first liquid.

The first flow-rate regulation valve 31 and the second flow-rate regulation valve 32 are coupled to the operation controller 47, and operations of the first flow-rate regulation valve 31 and the second flow-rate regulation valve 32 are controlled by the operation controller 47. When the operation controller 47 opens the first flow-rate regulation valve 31 with the second flow-rate regulation valve 32 closed, the polishing liquid as the first liquid is supplied onto the polishing surface 2a of the polishing pad 2. When the operation controller 47 opens the second flow-rate regulation valve 32 with the first flow-rate regulation valve 31 closed, a second liquid different from the polishing liquid is supplied onto the polishing surface 2a of the polishing pad 2.

Polishing of the wafer W is performed as follows. While the polishing head 7 and the polishing table 5 are rotated, the polishing liquid is supplied from the liquid nozzle 9 of the liquid supply device 8 onto the polishing surface 2a of the polishing pad 2. An example of the polishing liquid supplied to the polishing pad 2 is slurry containing abrasive grains. The polishing pad 2 rotates around its axis together with the polishing table 5. The polishing head 7 is lowered to a predetermined polishing position by the elevating mechanism (not shown). Further, the polishing head 7 presses the wafer W against the polishing surface 2a of the polishing pad 2 with a predetermined pressure at the polishing position. The wafer W is in sliding contact with the polishing surface 2a of the polishing pad 2 in the presence of the polishing liquid on the polishing surface 2a of the polishing pad 2. The surface of the wafer W is polished by a combination of a chemical action of the polishing liquid supplied onto the polishing surface 2a and a mechanical action of the polishing pad 2 and/or the abrasive grains contained in the polishing liquid.

The optical information analyzer 13 includes a memory 13a storing programs therein and an arithmetic device 13b configured to perform arithmetic operations according to instructions included in the programs. The memory 13a includes a main memory, such as a random access memory (RAM), and an auxiliary memory, such as a hard disk drive (HDD) or a solid state drive (SSD). Examples of the arithmetic device 13b include a CPU (central processing unit) and a GPU (graphic processing unit). However, the specific configuration of the optical information analyzer 13 is not limited to this embodiment.

The operation controller 47 includes a memory 47a storing programs therein, and an arithmetic device 47b configured to perform arithmetic operations according to instructions included in the programs. The memory 47a includes a main memory, such as a random access memory (RAM), and an auxiliary memory, such as a hard disk drive (HDD) or a solid state drive (SSD). Examples of the arithmetic device 47b include a CPU (central processing unit) and a GPU (graphic processing unit). However, the specific configuration of the operation controller 47 is not limited to this embodiment.

Each of the optical information analyzer 13 and the operation controller 47 may be composed of one computer or a plurality of computers. Alternatively, the optical information analyzer 13 and the operation controller 47 may be composed of one computer. The optical information analyzer 13 and the operation controller 47 do not have to be physically independent, and may be virtually constructed by at least one computer.

The liquid monitoring device 12 is arranged above the polishing pad 2 and is oriented toward the polishing surface 2a. More specifically, the liquid monitoring device 12 is oriented toward at least a monitoring region M, which is located upstream of the polishing head 7 in the rotation direction of the polishing table 5 and the polishing pad 2. The liquid monitoring device 12 is configured to obtain optical information contained in light from the monitoring region M. The monitoring region M extends in the radial direction of the polishing pad 2. In one embodiment, a plurality of monitoring regions may be set. These monitoring regions extend in the radial directions of the polishing pad 2 and are arranged along a circumferential direction of the polishing pad 2. One of the plurality of monitoring regions is located upstream of the polishing head 7, as indicated by a symbol M in FIG. 1.

The polishing apparatus further includes a light source 40 configured to irradiates the polishing surface 2a of the polishing pad 2 with light having one or more wavelengths in a range of 200 nm to 1100 nm. The light source 40 is configured to emit at least visible light and includes, for example, a light emitting diode. It is desirable that the light source 40 uniformly illuminates the polishing surface 2a of the polishing pad 2. For example, the light source 40 may have a plurality of light emitting diodes or may have a light dispersion plate. The light source 40 is arranged so as to direct a uniform light to at least the monitoring region M.

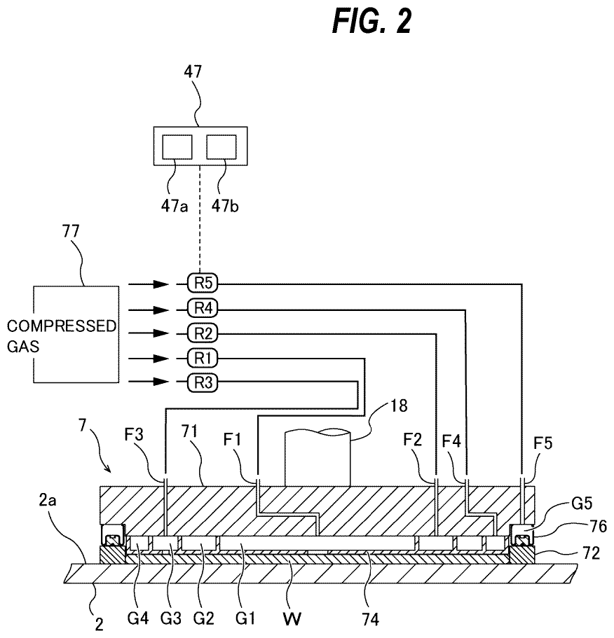

FIG. 2 is a cross-sectional view of the polishing head 7 shown in FIG. 1. The polishing head 7 includes a carrier 71 fixed to the polishing-head shaft 18, and a retainer ring 72 arranged below the carrier 71. A flexible membrane (or an elastic film) 74 that is brought into contact with the wafer W is held on a lower portion of the carrier 71. Four pressure chambers G1, G2, G3 and G4 are formed between the membrane 74 and the carrier 71. The pressure chambers G1, G2, G3 and G4 are formed by the membrane 74 and the carrier 71. The central pressure chamber G1 is circular, and the other pressure chambers G2, G3, and G4 are annular. These pressure chambers G1, G2, G3 and G4 are concentrically arranged. In one embodiment, five or more pressure chambers may be provided, or three or less pressure chambers may be provided.

Compressed gas, such as compressed air, is supplied from a gas supply source 77 to the pressure chambers G1, G2, G3, and G4 via fluid passages F1, F2, F3, and F4, respectively. The wafer W is pressed against the polishing surface 2a of the polishing pad 2 by the membrane 74. More specifically, the pressures of the compressed gas in the pressure chambers G1, G2, G3, and G4 act on the wafer W via the membrane 74 and press the wafer W against the polishing surface 2a. The pressures in the pressure chambers G1, G2, G3, G4 can be changed independently, so that polishing pressures on corresponding four regions of the wafer W, namely a central portion, an inner intermediate portion, an outer intermediate portion, and a peripheral edge portion, can be adjusted independently.

An annular rolling diaphragm 76 is arranged between the carrier 71 and the retainer ring 72, and a pressure chamber G5 is formed inside the rolling diaphragm 76. The pressure chamber G5 communicates with the gas supply source 77 via a fluid passage F5. The gas supply source 77 supplies the compressed gas into the pressure chamber G5, and the compressed gas in the pressure chamber G5 presses the retainer ring 72 against the polishing surface 2a of the polishing pad 2 via the rolling diaphragm 76.

The peripheral edge portion of the wafer W and a lower surface (i.e., a wafer pressing surface) of the membrane 74 are surrounded by the retainer ring 72. During polishing of the wafer W, the retainer ring 72 presses the polishing surface 2a of the polishing pad 2 outside the wafer W to prevent the wafer W from coming off from the polishing head 7 during polishing.

The fluid passages F1, F2, F3, F4, F5 extend from the pressure chambers G1, G2, G3, G4, G5 to the gas supply source 77. Pressure regulators R1, R2, R3, R4, and R5 are attached to the fluid passages F1, F2, F3, F4, and F5, respectively. The compressed gas is supplied from the gas supply source 77 into the pressure chambers G1 to G5 through the pressure regulators R1 to R5 and the fluid passages F1 to F5.

The pressure regulators R1, R2, R3, R4, and R5 are configured to regulate the pressures in the pressure chambers G1, G2, G3, G4, and G5. The pressure regulators R1, R2, R3, R4 and R5 are coupled to the operation controller 47. The operation controller 47 is configured to generate target pressure values for the respective pressure chambers G1 to G5. The operation controller 47 sends the target pressure values to the pressure regulators R1 to R5, and the pressure regulators R1 to R5 operate such that the pressures in the pressure chambers G1 to G5 are maintained at the corresponding target pressure values, respectively.

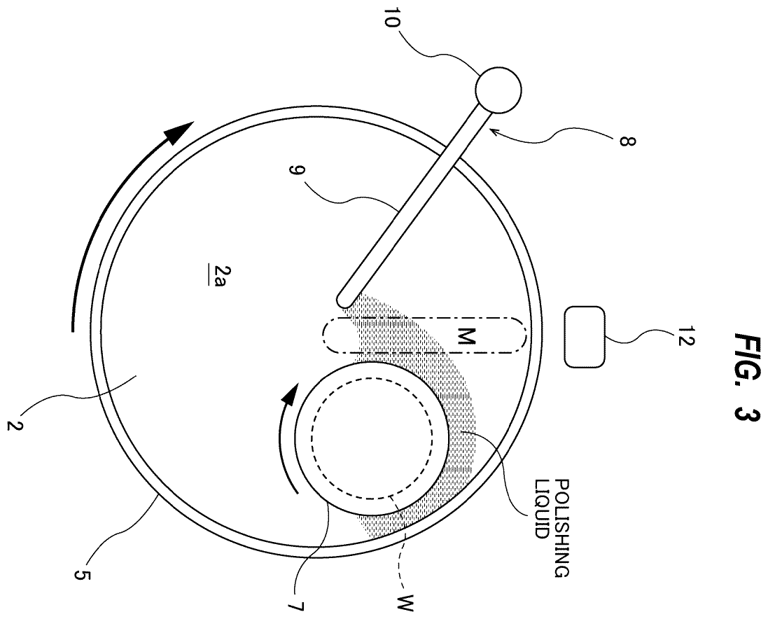

FIG. 3 is a plan view of the polishing pad 2, the liquid supply device 8, and the polishing head 7. As shown in FIG. 3, the polishing liquid is supplied from the liquid nozzle 9 of the liquid supply device 8 to a region near the center of the polishing surface 2a of the polishing pad 2. The polishing liquid on the rotating polishing pad 2 comes into contact with the wafer W held by the polishing head 7 while spreading outward in the radial direction due to centrifugal force. Immediately after the start of supply of the polishing liquid, the polishing liquid does not yet sufficiently spread on the polishing surface 2a. Therefore, normally, after a preset time has elapsed from the start of supply of the polishing liquid, the polishing head 7 presses the wafer W against the polishing surface 2a.

The liquid monitoring device 12 is configured to obtain optical information contained in light from the polishing surface 2a of the polishing pad 2 and light from the liquid (for example, the polishing liquid) existing on the polishing surface 2a. Specific examples of the optical information include color of the polishing surface 2a and the liquid (i.e., a color distribution on the polishing surface 2a), quantity of the light from the polishing surface 2a and the liquid, etc. In this embodiment, the liquid monitoring device 12 includes an image sensor configured to generate a color image. Examples of the image sensor include a CCD sensor and a COMS sensor. The liquid monitoring device 12 is configured to generate a color image of the monitoring region M in the polishing surface 2a and obtain a color distribution as the optical information appearing on the color image.

Usually, the polishing liquid and the polishing pad 2 have different colors. Therefore, the polishing liquid existing on the polishing surface 2a of the polishing pad 2 is visually distinguishable from the polishing surface 2a. The optical information analyzer 13 is coupled to the liquid monitoring device 12, and obtains the color image from the liquid monitoring device 12. Further, the optical information analyzer 13 perform image processing on the color image to determine a distribution of the amount of polishing liquid existing on the polishing surface 2a. More specifically, the optical information analyzer 13 determines liquid-color index values each representing a color depth (or color density) of the polishing liquid in the monitoring region M from the color image, and creates a graph of a polishing-liquid amount distribution showing amounts of polishing liquid expressed by the liquid-color index values at respective positions in the monitoring region M.

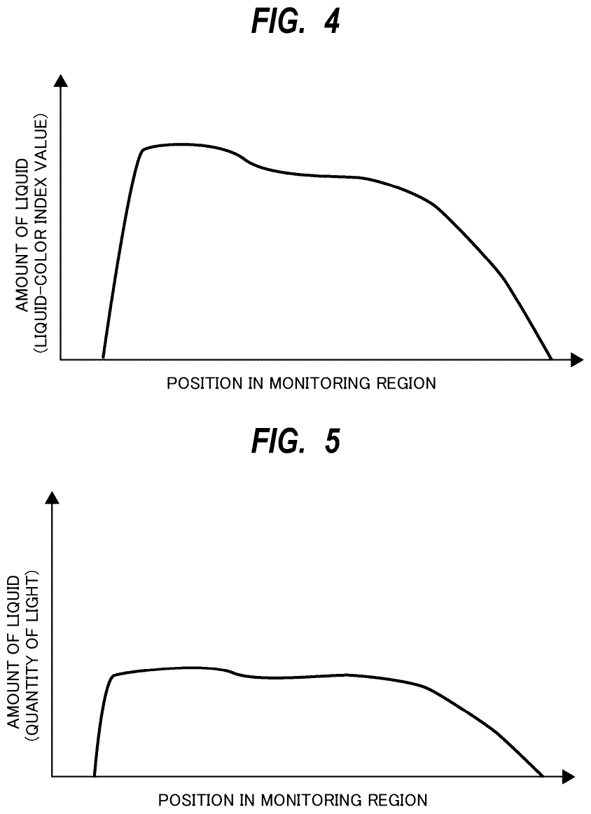

FIG. 4 is a diagram showing an example of the graph of the polishing-liquid amount distribution. In FIG. 4, vertical axis represents the amount of liquid corresponding to the liquid-color index value, and horizontal axis represents position in the monitoring region M. In the example shown in FIG. 4, the position represented by the horizontal axis is a position in the radial direction of the polishing pad 2. Since the liquid-color index value changes depending on the amount of the polishing liquid existing on the polishing surface 2a, the liquid-color index value corresponds to the amount of the polishing liquid. The vertical axis of FIG. 4 represents the amount of the polishing liquid expressed using the liquid-color index value.

The liquid-color index value can vary depending on color model (or color space) that defines the colors in the color image. Examples of the color model used to express colors quantitatively include RGB, CMY, CMYK, HSL, HSV, etc.

The liquid-color index value may be a numerical value of only one of a plurality of components that define each color model. For example, the RGB color model uses three components of R (red), G (green), and B (blue) as primary colors. The liquid-color index value may be represented by a numerical value of only one of these three components. In one example, each component of R (red), G (green), and B (blue) is represented by a numerical value in a range of 0 to 255. Using only one component may make it possible to accurately detect the polishing liquid on the polishing surface 2a.

In one embodiment, the optical information analyzer 13 may determine the liquid-color index value using a synthetic value of luminosity or brightness in addition to each component of the color model (or color space). The luminosity is an average of maximum and minimum values of each component of RGB, and the brightness is a brightness that the human eye perceives. Specifically, the brightness is calculated from red component (R)×0.21+green component (G)×0.72+blue component (B)×0.07. In this way, the optical information analyzer 13 can obtain a relative distribution of the polishing liquid on the polishing pad 2 by analyzing the color image reflecting the shading of the polishing liquid on the polishing pad 2. Further, the optical information analyzer 13 may be configured to obtain data indicating a relationship between a thickness of a film of the polishing liquid and the color in advance, and determine a film-thickness distribution of the polishing liquid existing on the polishing surface 2a from the color image.

When the color of the polishing liquid is close to the color of the polishing pad 2, or when the polishing liquid is transparent, it may be difficult to obtain the distribution of the amount of the polishing liquid on the polishing pad 2 by processing the color image. Thus, in one embodiment, the liquid monitoring device 12 has a light-detection sensor configured to measure quantity of light, which is another example of the optical information, instead of the image sensor that generates a color image. In one example, the light-detection sensor is configured to measure the quantity of light having one or more wavelengths in a range of 200 nm to 1100 nm. An example of the light-detection sensor is a photodiode.

The liquid monitoring device 12 having the light detection sensor measures the quantity of light reflected from the polishing liquid in the monitoring region M, and transmits measurement data of the quantity of light to the optical information analyzer 13. The optical information analyzer 13 is configured to determine the distribution of the amount of polishing liquid on the polishing surface 2a based on the measurement data of the quantity of light. In a region where the polishing liquid exists on the polishing surface 2a of the polishing pad 2, the light is easily reflected by the polishing liquid, and as a result, the quantity of light becomes large. Therefore, the optical information analyzer 13 can determine the distribution of the amount of polishing liquid on the polishing surface 2a based on the measurement data of the quantity of light obtained by the liquid monitoring device 12.

FIG. 5 is a diagram showing an example of a graph of the distribution of the amount of polishing liquid. In FIG. 5, vertical axis represents the amount of liquid corresponding to the quantity of light reflected from the polishing liquid, and horizontal axis represents position in the monitoring region M. In the example shown in FIG. 5, the position represented by the horizontal axis is a position in the radial direction of the polishing pad 2. Since the quantity of light reflected from the polishing liquid changes depending on the presence or absence of the polishing liquid on the polishing surface 2a, the quantity of light corresponds to the amount of the polishing liquid existing on the polishing surface 2a. The vertical axis of FIG. 5 represents the amount of the polishing liquid expressed using the quantity of light.

In one embodiment, the light-detection sensor of the liquid monitoring device 12 may be an infrared sensor. The polishing surface 2a and the polishing liquid emit infrared rays depending on their temperature. During the polishing of the wafer W, the temperature of the polishing surface 2a of the polishing pad 2 rises due to the sliding contact with the wafer W. In contrast, the temperature of the polishing liquid is generally a room temperature. Therefore, there is a temperature difference between the polishing surface 2a and the polishing liquid. Intensities of infrared rays emitted from the polishing surface 2a and the polishing liquid vary depending on these temperatures. The liquid monitoring device 12 including the infrared sensor measures the intensity of infrared ray in the monitoring region M, and transmits measured data of the intensity of infrared ray to the optical information analyzer 13. The optical information analyzer 13 determines the distribution of the amount of polishing liquid on the polishing surface 2a based on the measurement data of the intensity of infrared ray. The intensity of infrared ray corresponds to the amount of polishing liquid present on the polishing surface 2a. In the case where the infrared sensor is used, the light source 40 shown in FIG. 1 may be omitted.

If the color of the polishing liquid is close to the color of the polishing pad 2, or if the polishing liquid is transparent, colored water may be used for analyzing a distribution of an amount of the colored water on the polishing surface 2a during an interval time before or after polishing of the wafer W (e.g., when the polishing apparatus is in an idling operation). More specifically, during the interval time before or after polishing of the wafer W, the operation controller 47 closes the first flow-rate regulation valve 31 shown in FIG. 1 and opens the second flow-rate regulation valve 32 to supply the colored water as the second liquid from the liquid supply device 8 onto the polishing surface 2a of the polishing pad 2. Examples of the colored water include black water containing carbon. The operation controller 47 instructs the liquid monitoring device 12 to obtain the optical information contained in the light from the polishing surface 2a and the colored water. More specifically, the liquid monitoring device 12 generates a color image of the colored water on the polishing surface 2a and sends the color image to the optical information analyzer 13. The optical information analyzer 13 can determine the distribution of the amount of colored water on the polishing surface 2a by analyzing the color image. Depending on the colors of the colored water and the polishing surface 2a of the polishing pad 2, the obtained distribution of the optical information (for example, the brightness value) and the distribution of the actual amount of liquid may be reversed. In that case, the distribution of the amount of liquid may be determined by using data processing, such as reversing the brightness value.

As the liquid to be supplied during the interval time, pure water may be used instead of the colored water. The operation controller 47 closes the first flow-rate regulation valve 31 shown in FIG. 1 and opens the second flow-rate regulation valve 32 during the interval time before or after polishing of the wafer W to supply pure water as the second liquid from the liquid supply device 8 onto the polishing surface 2a of the polishing pad 2. In this case, according to the other embodiment described above, the liquid monitoring device 12 measures the quantity of light reflected from the pure water in the monitoring region M, transmits measurement data of the quantity of light to the optical information analyzer 13. The optical information analyzer 13 determines the distribution of the amount of pure water on the polishing surface 2a based on the measurement data of the quantity of light.

Further, as the liquid to be supplied during the interval time, a chemical liquid may be used instead of the colored water. In this case also, the distribution of the amount of the chemical liquid on the polishing surface 2a can be determined in the same manner as in the above-described embodiment.

The polishing liquid used to polish a wafer is generally expensive. The above embodiment in which the colored water, the pure water, or the chemical liquid is used instead of the polishing liquid can reduce the cost required for obtaining the distribution of the amount of liquid on the polishing surface 2a.

Depending on the polishing process, a polishing by-product may color the polishing surface 2a of the polishing pad 2. For example, in copper polishing, copper ions in the polishing by-product are mixed with the polishing liquid and color the polishing surface 2a of the polishing pad 2, resulting in color contrast of the colored polishing surface 2a and the liquid, such as the polishing liquid, supplied from the liquid supply device 8. The liquid monitoring device 12 generates a color image of the colored polishing surface 2a, and the optical information analyzer 13 determines a color distribution of the polishing surface 2a from the color image. This color distribution can be used as the distribution of the amount of liquid on the polishing pad 2.

During polishing of the wafer W, it is desirable that the polishing liquid is uniformly distributed on the polishing surface 2a. This is because a polishing rate of a film of the wafer W can change depending on the amount of the polishing liquid present on the polishing surface 2a. Thus, the operation controller 47 is configured to instruct the liquid monitoring device 12 to obtain the optical information of the polishing surface 2a at a plurality of points in time during polishing of the wafer W (for example, to generate a plurality of color images). The optical information analyzer 13 is configured to obtain a temporal transition of the distribution of the amount of the polishing liquid by analyzing the optical information obtained at the plurality of points in time.

If the distribution of the amount of polishing liquid on the polishing surface 2a changes during polishing of the wafer W, the operation controller 47 may change polishing conditions for the wafer W so as to restore the distribution of the amount of polishing liquid. More specifically, the operation controller 47 calculates a difference between a plurality of distributions of the amount of the polishing liquid determined at a plurality of points in time during polishing of the wafer W. If the difference in distribution is larger than a permissible value, the operation controller 47 determines that the distribution of the amount of polishing liquid is abnormal, and changes the polishing conditions in a direction as to reduce the difference in distribution. For example, the operation controller 47 changes at least one of a rotation speed of the polishing head 7, a rotation speed of the polishing table 5, a flow rate of the polishing liquid supplied from the liquid supply device 8, and the oscillation of the liquid nozzle 9 so as to reduce the above difference in distribution. Such operation can prevent an unintended change in the polishing rate of the wafer W and a polishing-rate distribution.

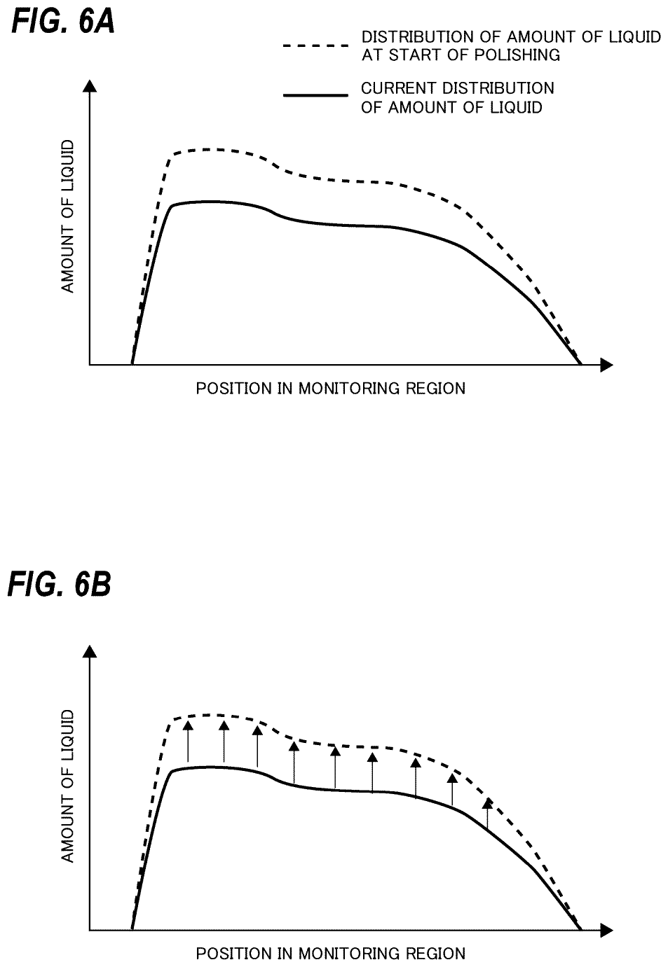

FIGS. 6A and 6B are graphs each showing the distribution of the amount of polishing liquid that has been changed during polishing of one wafer W. As shown in FIG. 6A, during polishing of the wafer W, the current distribution of the amount of the polishing liquid may decrease from the distribution of the amount of the polishing liquid at the start of polishing of the wafer W. The operation controller 47 calculates a difference between these distributions of the polishing liquid, and when the difference in distribution is larger than a permissible value, the operation controller 47 changes the polishing conditions for the wafer W in the direction as to reduce the difference, as shown in FIG. 6B. For example, the operation controller 47 increases the opening degree of the first flow-rate regulation valve 31 to increase the flow rate of the polishing liquid supplied to the polishing surface 2a. When the distribution of the amount of polishing liquid is biased to an inner peripheral side or an outer peripheral side of the polishing pad 2, the operation controller 47 may instruct the polishing-table rotating device 21 to increase or decrease the rotation speed of the polishing table 5.

In one embodiment, after a predetermined time has elapsed since the operation controller 47 has changed the polishing conditions of the polishing apparatus, the optical information analyzer 13 may re-determine the current distribution of the amount of the polishing liquid during the polishing of the wafer W, and the operation controller 47 may calculate a difference between the distribution of the amount of the polishing liquid at the start of polishing of the wafer W and the re-determined current distribution of the amount of the polishing liquid, and may stop the operation of the polishing apparatus before polishing of a next wafer if the calculated difference in distribution is larger than the permissible value.

Further, in one embodiment, the operation controller 47 may calculate a difference in a plurality of distributions of the amount of the polishing liquid determined at a plurality of points in time during polishing of the wafer W, and if the difference in distribution is larger than a permissible value, the operation controller 47 may stop the operation of the polishing apparatus before polishing of a next wafer without changing the polishing conditions for the wafer W.

Further, in one embodiment, the operation controller 47 may calculate a difference in a plurality of distributions of the amount of the polishing liquid determined at a plurality of points in time during polishing of the wafer W, and if the difference in distribution is larger than a permissible value, the operation controller 47 may change the pressing force of the polishing head 7 against the wafer W. As shown in FIG. 6A, when the distribution of the amount of the polishing liquid is decreasing during polishing of the wafer W, the polishing rate of the wafer W is expected to decrease due to the decrease in the amount of the polishing liquid. Therefore, in order to compensate for the decrease in the polishing rate, the operation controller 47 increases the pressing force of the polishing head 7 against the wafer W. Specifically, the operation controller 47 instructs at least one of the pressure regulators R1 to R4 shown in FIG. 2 to increase the pressure in at least one of the pressure chambers G1 to G4 of the polishing head 7. As a result, the polishing head 7 can press the wafer W against the polishing pad 2 with a higher pressing force and can maintain the intended polishing rate.

Causes that change the distribution of the amount of polishing liquid on the polishing surface 2a of the polishing pad 2 during polishing include device failure, a change in physical properties (viscosity, etc.) of the polishing liquid due to the temperature rise of the polishing pad 2, and a change in a surface condition of the polishing pad 2. When the cause is a device failure, such device failure can be detected based on the monitoring of the distribution of the amount of polishing liquid on the polishing pad 2.

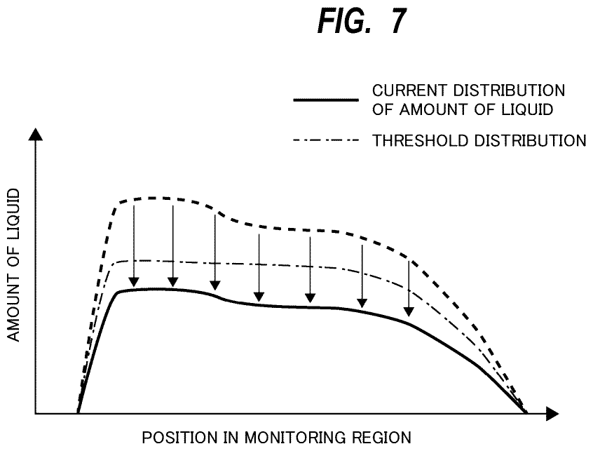

In one embodiment, when the distribution of the liquid (for example, polishing liquid, pure water, chemical liquid, or colored water) falls below a preset threshold distribution, the operation controller 47 may determine that an abnormality has occurred in the polishing apparatus. For example, as shown in FIG. 7, when the entire distribution of the amount of the liquid falls below the preset threshold distribution (or reference distribution), possible cause of this may be clogging of the liquid nozzle 9 or the first liquid supply line 25 (see FIG. 1). The operation controller 47 may generate an alarm signal when the distribution of the amount of the liquid falls below the preset threshold distribution.

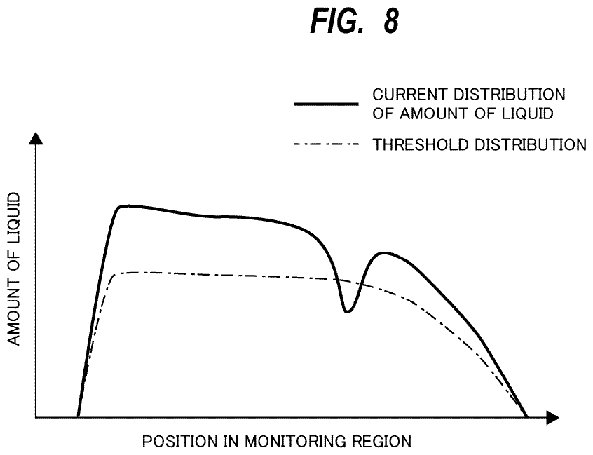

The liquid nozzle 9 shown in FIG. 1 has one supply port 9a at its distal end, while in another embodiment, the liquid nozzle 9 may have a plurality of supply ports arranged along the radial direction of the polishing pad 2. With this configuration, the liquid nozzle 9 can easily form a uniform liquid film on the polishing surface 2a of the polishing pad 2. However, if any one of the plurality of supply ports is clogged, the distribution of the amount of the liquid is locally reduced. On the other hand, such clogging of one supply port does not cause a substantial change in the flow rate of the liquid as a whole. Therefore, it is difficult to detect the clogging of one supply port based on the change in the flow rate. According to the above embodiment that monitors the distribution of the amount of the liquid, as shown in FIG. 8, when the distribution of the amount of the liquid falls below the threshold distribution, the operation controller 47 determines the occurrence of an abnormality and can therefore detect local clogging of the liquid nozzle 9.

Normally, for controlling the flow of the polishing liquid, a plurality of grooves are formed in the polishing surface 2a of the polishing pad 2. The polishing pad 2 gradually wears as many wafers are polished, and depths of the grooves in the polishing surface 2a gradually decrease. As a result, the distribution of the amount of polishing liquid on the polishing surface 2a may change even if the flow rate of the polishing liquid supplied from the liquid supply device 8 does not change.

Therefore, in order to check the change in the distribution of the amount of the polishing liquid with time, in an embodiment described below, the distribution of the amount of the liquid when the polishing pad 2 is not used and the distribution of the amount of the liquid when the polishing pad 2 is used are compared. More specifically, the operation controller 47 is configured to instruct the liquid monitoring device 12 to obtain initial optical information of the polishing surface 2a of the polishing pad 2 that has not been used for polishing yet and to obtain current optical information of the polishing surface 2a of the polishing pad 2 that has been used for polishing. The polishing pad 2 that has not been used for polishing yet is a new polishing pad that has not been used for polishing a wafer.

The liquid to be used is either the polishing liquid, the pure water, the chemical liquid, or the colored water. Since the polishing liquid is generally expensive, the liquid to be used is preferably either the pure water, the chemical liquid, or the colored water. Specific examples of the optical information of the polishing surface 2a include the color distribution on the polishing surface 2a, the quantity of light from the polishing surface 2a and the liquid, etc. As described above, the liquid monitoring device 12 includes the image sensor, the light detection sensor, or the infrared sensor. For example, the liquid monitoring device 12 generates an initial color image of the liquid on the polishing surface 2a of the polishing pad 2 that has not been used for polishing yet, and generates a latest color image of the liquid on the polishing surface 2a of the polishing pad 2 that has been used for polishing. Alternatively, the liquid monitoring device 12 measures an initial quantity of light from the liquid on the polishing surface 2a of the polishing pad 2 that has not been used for polishing yet, and measures a latest quantity of light from the liquid on the polishing surface 2a of the polishing pad 2 that has been used for polishing.

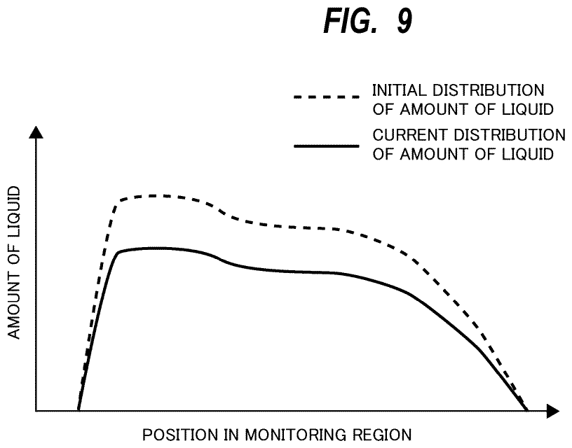

The optical information analyzer 13 determines an initial distribution of the amount of the liquid on the polishing surface 2a from the initial optical information (for example, the initial color image or the measurement data of the initial quantity of light), and determines a current distribution of the amount of the liquid on the polishing surface 2a from the current optical information (for example, the latest color image or the measurement data of the latest quantity of light). FIG. 9 is a graph showing the initial distribution of the amount of liquid on the polishing surface 2a and the current distribution of the amount of liquid on the polishing surface 2a. As shown in FIG. 9, the distribution of the amount of liquid on the polishing surface 2a changes with time due to the wear of the polishing pad 2.

The operation controller 47 receives data on the initial distribution and the current distribution of the amount of liquid on the polishing surface 2a from the optical information analyzer 13 and stores them in the memory 47a. The operation controller 47 is configured to determine a condition of the polishing pad 2 from a difference between the initial distribution and the current distribution of the amount of liquid on the polishing surface 2a. More specifically, the operation controller 47 is configured to calculate the difference between the initial distribution and the current distribution of the amount of liquid on the polishing surface 2a, and generate an alarm signal indicating the wear of the polishing pad 2 if this difference in distribution is larger than a threshold value.

When the difference between the initial distribution and the current distribution of the amount of liquid on the polishing surface 2a is larger than the threshold value, the operation controller 47 may change the polishing conditions for the wafer in the direction as to reduce the difference in distribution. More specifically, the operation controller 47 changes at least one of the rotation speed of the polishing head 7, the rotation speed of the polishing table 5, the flow rate of the liquid supplied from the liquid supply device 8, and the oscillation of the liquid nozzle 9 so as to reduce the above difference in distribution. Such operation can prevent an unintended change in the polishing rate of the wafer and the polishing-rate distribution.

In one embodiment, after a predetermined time has elapsed since the operation controller 47 has changed the polishing conditions, the optical information analyzer 13 may redetermine the current distribution of the amount of liquid on the polishing surface 2a, and the operation controller 47 may calculate a difference between the initial distribution of the amount of the liquid and the redetermined current distribution of the amount of the liquid, and if this difference in distribution is larger than the above threshold value, the operation controller 47 may stop the operation of the polishing apparatus before polishing of a next wafer.

Further, in one embodiment, when the difference between the initial distribution and the current distribution of the amount of liquid on the polishing surface 2a is larger than the threshold value, the operation controller 47 may stop the operation of the polishing apparatus before polishing of a next wafer without changing the polishing conditions for a wafer.

Further, in one embodiment, the operation controller 47 may change the pressing force of the polishing head 7 against the wafer if the difference between the initial distribution and the current distribution of the amount of liquid on the polishing surface 2a is larger than threshold value. As shown in FIG. 9, as the wear of the polishing pad 2 progresses, the amount of the polishing liquid on the polishing surface 2a of the polishing pad 2 decreases, and the polishing rate of the wafer is expected to decrease due to the decrease in the amount of the polishing liquid. Thus, the operation controller 47 increases the pressing force of the polishing head 7 against the wafer in order to compensate for the decrease in the polishing rate. Specifically, the operation controller 47 instructs at least one of the pressure regulators R1 to R4 shown in FIG. 2 to increase the pressure in at least one of the pressure chambers G1 to G4 of the polishing head 7. As a result, the polishing head 7 can press the wafer against the polishing pad 2 with a higher pressing force, and can maintain the intended polishing rate.

The permissible value and the threshold value to be compared with the difference between the distributions of the amount of the liquid on the polishing surface 2a may be determined from a difference between a distribution of the amount of the liquid in a normal condition and a distribution that has changed from the distribution of the amount of the liquid in the normal condition by a predetermined ratio (e.g., 10%). An example of the distribution of the amount of the liquid in the normal condition may be a distribution of the amount of the liquid when a polishing-rate profile of a wafer is normal.

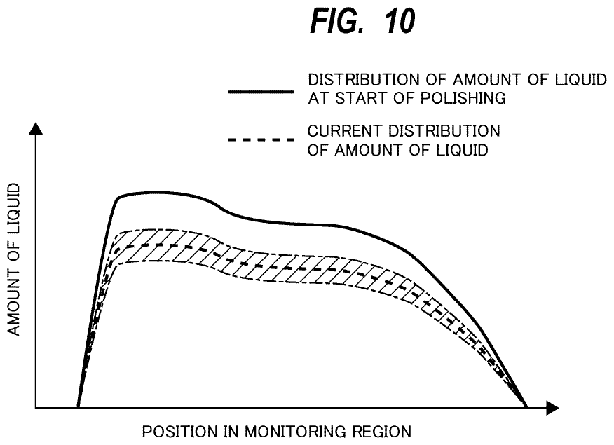

Due to a variation in manufacturing of the polishing pad 2, there may be a variation in the distribution of the amount of liquid even in the normal condition. In that case, the operation controller 47 may store, in its memory 47a, data of a plurality of distributions of the amount of liquid in the past normal condition, and may determine whether the above difference is within a range defined from the data, as shown in FIG. 10.

The permissible value and the threshold value to be compared to the difference between the distributions of the amount of liquid on the polishing surface 2a may be automatically determined by artificial intelligence (AI). For example, information on consumables, such as polishing pad and liquid, and information on the occurrence of polishing abnormalities may be combined with data of distributions of amount of liquid and stored in the memory 47a of the operation controller 47. Then, transition of the distribution of the amount of the liquid with respect to each combination of the polishing pad and the liquid is machine-learned by artificial intelligence (AI). As a result, when information on a consumable material is input to the operation controller 47, the permissible value and the threshold value can be determined automatically.

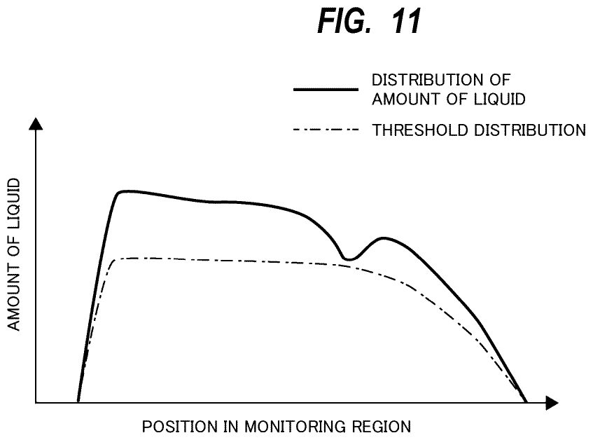

Further, as shown in FIG. 11, for example, when the abnormality of the distribution of the amount of the liquid is local and small, such abnormality may not be detected correctly. In that case, instead of the permissible value or the threshold value, a shape of the distribution of the amount of the liquid is used for determining normality and abnormality. This makes it possible to make an accurate judgment. Specifically, a distribution of the amount of the liquid at a time of occurrence of an abnormality is recognized as abnormality data via machine learning by the operation controller 47. As a result, the operation controller 47 can determine an abnormality when a similar distribution of the amount of liquid is detected.

In the embodiments described so far, the optical information analyzer 13 determines the distribution of the amount of liquid on the polishing surface 2a of the polishing pad 2 from the optical information (for example, color on the color image, the measurement data of the quantity of light, etc.) obtained from the liquid monitoring device 12. However, although not shown, there is a light-shielding object above the polishing pad 2, such as a dresser for dressing (regenerating) the polishing surface 2a of the polishing pad 2 or an atomizer for cleaning the polishing surface 2a. In addition, the quantity of light reflected off the liquid on the polishing pad 2 may vary depending on the position of the light source 40. Further, there is a color of the polishing pad 2 itself and its variation. The presence of such light-shielding object, the influence of the light source 40, and the color of the polishing pad 2 and the variation in its color may prevent the optical information analyzer 13 from determining the accurate distribution of the liquid on the polishing surface 2a.

Thus, in one embodiment described below, before the supply of the liquid, the operation controller 47 instructs the liquid monitoring device 12 to obtain a first optical information contained in the light from the polishing surface 2a of the polishing pad 2. Further, when the liquid is supplied, the operation controller 47 instructs the liquid monitoring device 12 to obtain a second optical information contained in the light from the polishing surface 2a. Subsequently, the optical information analyzer 13 determines a first distribution from the first optical information, determines a second distribution from the second optical information, and determines a distribution of the amount of the liquid by subtracting the first distribution from the second distribution.

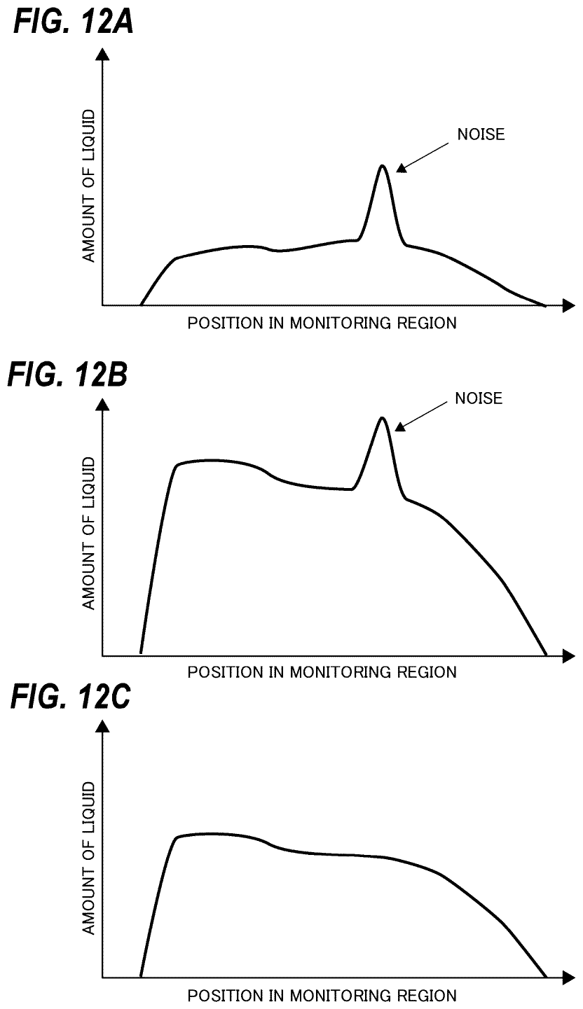

FIG. 12A is a graph showing the first distribution obtained from the first optical information of the polishing surface 2a obtained by the liquid monitoring device 12 before the liquid is supplied, FIG. 12B is a graph showing the second distribution obtained from the second optical information of the polishing surface 2a obtained by the liquid monitoring device 12 when the liquid is supplied, and FIG. 12C is a graph showing the distribution of the amount of the liquid obtained by subtracting the first distribution from the second distribution. As shown in FIGS. 12A and 12B, due to the light-shielding object (e.g., the dresser), a noise appears in the first distribution and the second distribution. Therefore, by subtracting the first distribution from the second distribution, a distribution of the amount of liquid from which noise has been removed can be obtained, as shown in FIG. 12C.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method for polishing an object, comprising:
while rotating a polishing head and a polishing table supporting a polishing pad, pressing the object against a polishing surface of the polishing pad by the polishing head to polish the object;
before, during, or after polishing of the object, obtaining optical information contained in light from a plurality of points on the polishing surface, while supplying a liquid onto the polishing surface; and
determining a distribution of amount of the liquid on the polishing surface from the optical information.

2. The polishing method according to claim 1, wherein the distribution of the amount of the liquid is determined by subtracting a first distribution from a second distribution, the first distribution being determined from first optical information of a plurality of points on the polishing surface obtained before the supply of the liquid, and the second distribution being determined from second optical information of a plurality of points on the polishing surface obtained when the liquid is supplied.

3. The polishing method according to claim 1, wherein obtaining the optical information comprises obtaining the optical information of a plurality of points on the polishing surface at a plurality of points in time during polishing of the object while supplying the liquid onto the polishing surface, and
determining the distribution of the amount of the liquid comprises obtaining a temporal transition of the distribution of the amount of the liquid on the polishing surface from the optical information of the plurality of points on the polishing surface obtained at the plurality of points in time.

4. The polishing method according to claim 1, wherein obtaining the optical information comprises obtaining the optical information while supplying the liquid onto the polishing surface at an interval time before or after polishing of the object.

5. The polishing method according to claim 1, further comprising: obtaining initial optical information of a plurality of points on the polishing surface while supplying the liquid onto the polishing surface of the polishing pad that has not been used for polishing yet;
obtaining current optical information of a plurality of points on the polishing surface while supplying the liquid onto the polishing surface of the polishing pad that has been used for polishing;
determining an initial distribution of the amount of the liquid on the polishing surface from the initial optical information;
determining a current distribution of the amount of the liquid on the polishing surface from the current optical information; and
calculating a difference between the initial distribution and the current distribution.

6. The polishing method according to claim 4, wherein the liquid supplied onto the polishing surface of the polishing pad while obtaining the optical information is a liquid of a different type from a polishing liquid used for polishing of the object.

7. The polishing method according to claim 1, wherein the optical information is quantity of light from the polishing surface.

8. The polishing method according to claim 1, wherein the optical information is a color distribution of the polishing surface.

9. The polishing method according to claim 1, wherein obtaining the optical information comprises obtaining the optical information of the plurality of points in a monitoring region located upstream of the polishing head in a rotation direction of the polishing table.

10. The polishing method according to claim 3, further comprising:
calculating a difference between a plurality of distributions of the amount of the liquid at the plurality of points in time during polishing of the object; and
changing polishing conditions for the object in a direction as to reduce the difference in distribution when the difference in distribution is larger than a permissible value.

11. The polishing method according to claim 10, further comprising:
recalculating a difference between a plurality of distributions of the amount of the liquid determined at a plurality of points in time during polishing of the object after the polishing conditions are changed; and
stopping operation of a polishing apparatus before polishing of a next object when the recalculated difference in distribution is larger than the permissible value.

12. The polishing method according to claim 3, further comprising:
calculating a difference between a plurality of distributions of the amount of the liquid determined at the plurality of points in time during polishing of the object; and
stopping operation of a polishing apparatus before polishing of a next object when the difference in distribution is larger than a permissible value.

13. The polishing method according to claim 3, further comprising:
calculating a difference between a plurality of distributions of the amount of the liquid determined at the plurality of points in time during polishing of the object; and
changing a pressing force of the polishing head against the object when the difference in distribution is larger than a permissible value.

14. The polishing method according to claim 5, further comprising:
changing polishing conditions for the object in a direction as to reduce the difference between the initial distribution and the current distribution of the amount of the liquid on the polishing surface when the difference is larger than a threshold value.

15. The polishing method according to claim 14, further comprising:
recalculating a difference between the initial distribution of the amount of the liquid and a current distribution of the amount of the liquid that has been newly determined after the polishing conditions have been changed; and
stopping operation of a polishing apparatus before polishing of a next object when the difference in distribution is larger than the threshold value.

16. The polishing method according to claim 5, further comprising:
stopping operation of a polishing apparatus before polishing of a next object when the difference between the initial distribution and the current distribution of the amount of the liquid on the polishing surface is larger than a threshold value.

17. The polishing method according to claim 1, further comprising:
determining that an abnormality has occurred in a polishing apparatus when the distribution of the amount of the liquid falls below a preset threshold distribution of the amount of the liquid.

18. The polishing method according to claim 1, wherein the liquid is one of a polishing liquid, pure water, a chemical liquid, and colored water.
